(19) United States
(12) Patent Application Publication
(10) Pub. No.: US 2026/0113889 A1
(43) Pub. Date: Apr. 23, 2026

(54) Heat sink

(71) Applicant: Tiger Tech Precision Parts (Huizhou) Co., Ltd., Huizhou (CN)

(72) Inventor: Yaoming Huang, Huizhou (CN)

(21) Appl. No.: 19/028,733

(22) Filed: Jan. 17, 2025

(30) Foreign Application Priority Data
Oct. 21, 2024 (CN) 2024114703909

(51) Int. Cl. H05K 7/20

(52) U.S. Cl. CPC H05K 7/20409

(57) ABSTRACT

A heat sink includes a bottom frame and heat dissipation element; a side of the bottom frame is provided with a recessed cavity for receiving a heat element, the other side of the bottom frame away from the recessed cavity is provided with a step groove, an inner bottom wall thereof is provided with a through slot in communication with the recessed cavity; the heat dissipation element includes a heat-conducting plate, a heat-conducting protrusion, and several heat dissipation teeth; each heat dissipation tooth is spaced apart on the same side of the heat-conducting plate, the heat-conducting protrusion is arranged on the side of the heat-conducting plate away from the heat dissipation teeth; the heat-conducting plate is accommodated in the step groove, and the heat-conducting protrusion is passed through the through slot; the outer wall of the heat-conducting protrusion is hermetically connected to the inner wall of the through slot.

### FIELD OF THE INVENTION

The disclosure relates to the technical fields of heat sinks, more particularly, to a heat sink.

### BACKGROUND OF THE INVENTION

Hear sinks are designed to help dissipate heat from heating elements such as electronic devices. They are generally composed of a series of vertically or horizontally arranged heat dissipation teeth, which can increase the contact area with the surrounding air, thereby accelerating the heat transfer rate from the heat source to the air. The design purpose of heat dissipation teeth is to maximize the efficiency of heat dissipation while maintaining structural stability and portability.

At present, heat sinks are mainly made by methods such as aluminum extrusion, die-casting, machining, and scraping (also known as scraping radiator), etc. However, as the size of heat sinks becomes larger and more suitable for heating elements such as electronic devices to improve the efficiency of heat dissipation, the structure of heat sinks becomes more complex, and the heat dissipation teeth becomes higher and higher. It is difficult to obtain the desired specific structure using aluminum extrusion, and the method of die-casting integrated molding increases the cost significantly with the increase in size and structural specificity of the heat sinks, and longer heat dissipation teeth increase the difficulty of demolding, resulting in limited tooth height. The heat sinks produced by die-casting integrated molding have relatively low heat dissipation efficiency due to material reasons, and the qualification rate of die casting molding is also relatively low. Although machining can carve the shape required for heat sinks, the processing efficiency is low and the cost of mass production is too high. Although scraping can achieve high heat dissipation efficiency, it cannot be applied to components with slightly more complex structures. In view of this, in order to address the above problems, the heat sinks and the manufacturing method in the disclosure are proposed.

### SUMMARY

The object of the disclosure is to overcome the deficiencies of the prior art and provide a heat sink and a method for producing the same that is easy to manufacture and convenient for mass production has a high pass rate and better thermal conductivity.

The object of the disclosure is achieved through the following technical solutions:

A heat sink includes a bottom frame and a heat dissipation element. A side of the bottom frame is provided with a recessed cavity for receiving a heat element, the other side of the bottom frame away from the recessed cavity is provided with a step groove, an inner bottom wall of the step groove is provided with a through slot in communication with the recessed cavity.

The heat dissipation element includes a heat-conducting plate, a heat-conducting protrusion, and several heat dissipation teeth. Each heat dissipation tooth is spaced apart on the same side of the heat-conducting plate, and the heat-conducting protrusion is arranged on the side of the heat-conducting plate away from the heat dissipation teeth. The heat-conducting plate is adaptively accommodated in the step groove, and the heat-conducting protrusion is passed through the through slot. The outer wall of the heat-conducting protrusion is hermetically connected to the inner wall of the through slot.

Optionally, the outer wall of the heat-conducting protrusions is welded to the inner wall of the through slot.

Optionally, the outer wall of the heat-conducting protrusion and the inner wall of the through slot are welded by stir friction welding.

Optionally, the bottom frame includes a frame body and two surrounding plates. The recessed cavity, the step groove, and the through slot all are located in the frame body. The two surrounding plates are both provided on a sidewall of the frame body close to the step groove and located on two opposite sides of the stepped groove.

Optionally, the outer wall of the frame body is provided with two external connection lugs at intervals.

Optionally, the frame body, the two surrounding plates, the two external connection lugs are integrally formed into the bottom frame using die casting.

Optionally, a closed sealing groove is formed on the frame surrounding the periphery of the recessed cavity.

Optionally, the frame body is provided with a plurality of locking holes spaced apart from each other.

Optionally, the surface of the heat sink is provided with a protective layer.

A methods for producing the heat sink includes the following steps:

Step S10: manufacturing the bottom frame using die casting, a recessed cavity is provided on one side of the bottom frame, a step groove is provided on the other side, and a through slot communicating with the recessed cavity is also provided on an inner bottom wall of the step groove;

Step S20: acquiring the heat dissipation element, which includes the heat-conducting plate, the heat-conducting protrusion, and a plurality of the heat dissipation teeth, the heat-conducting protrusion is located on one side of the heat-conducting plate, and each heat dissipation tooth is located on the other side of the heat-conducting plate;

Step 30: the heat dissipation element is installed on the bottom frame, the heat-conducting plate is adaptively accommodated in the stepped groove, and the heat-conducting protrusion passes through the through slot.

Step S40: the outer sidewall of the heat-conducting protrusion is hermetically connected with the inner sidewall of the through slot to form the heat sink.

Compared with the prior art, the heat sink in the disclosure at least has the following advantages:

The heat sink in the disclosure includes the bottom frame and the heat dissipation member. The recessed cavity for accommodating the heat dissipation element is provided on one side of the bottom frame, the step groove is further provided on the side of the bottom frame away from the recessed cavity, the through slot in communication with the recessed cavity is provided on the inner bottom wall of the step groove, the heat dissipation element comprises the heat-conducting plate, the heat-conducting protrusion and a plurality of the heat dissipation teeth, and the heat dissipation teeth are arranged at intervals on the same side of the heat-conducting plate, the heat-conducting protrusion is provided on the side of the heat-conducting plate away from the heat dissipation teeth, and the heat-conducting plate is adaptively accommodated in the stepped groove. The heat-conducting protrusion penetrates through the through slot, and the outer side wall of the heat-conducting protrusion is hermetically connected to the inner side wall of the through slot. In this way, the heat sink is configured as a structure in which the bottom frame and the heat dissipation element are mounted in combination, where the heat dissipation element may be manufactured by processes such as extruding aluminum, machining copper or aluminum, relieving tooth, and even die-casting a high thermal conductivity material, The bottom frame is made using die casting, and therefore even if the structure design of the bottom frame is specific, the manufacturing difficulty of the heat sink can be greatly reduced, and the qualified rate of the heat sink can be effectively improved. It is convenient for mass production, and at the same time can effectively ensure that the assembled heat sink has excellent heat conduction and heat dissipation performance.

### BRIEF DESCRIPTION OF THE DRAWINGS

In order to clearly illustrate the technical solutions in the embodiments of the disclosure, the drawings to be used in the description of the embodiments or the existing technologies will be briefly described below, and it will be apparent that the drawings described below are only some embodiments of the disclosure, and for those of ordinary skill in the art, other attached drawings can be obtained according to these attached drawings without creative labor.

FIG. 1 is a perspective view of the heat sink according to an embodiment in the disclosure.

FIG. 2 is an exploded view of the heat sink shown in FIG. 1.

FIG. 3 is another exploded view of the heat sink shown in FIG. 1.

FIG. 4 is a sectional view of the heat sink shown in FIG. 1.

FIG. 5 is a flowchart of a method for producing the heat sink shown in FIG. 1.

The reference numbers are as follows:
10. The heat sink;
200. The bottom frame;
111. The recessed cavity;
112. The step groove;
113. The through slot;
210. The heat-conducting plate;
220. The heat-conducting protrusion;
230. The heat dissipation tooth;
110. The frame body;
120. The surrounding plate;
130. The external connection lug;
114. The sealing groove;
115. The locking hole.

### DETAILED DESCRIPTION OF ILLUSTRATED EMBODIMENTS

In order to facilitate an understanding of the disclosure, the disclosure will now be described more fully hereinafter with reference to the accompanying drawings. Preferred embodiments of the disclosure are shown in the drawings.

In the description of embodiments of the present invention, it is to be understood that the terms “length”, “width”, “up”, “down ”, “front”, “back”, “left”, “right”, “vertical”, ‘horizontal’, ‘top’, ‘bottom’, “inner”, “outer” and the like indicate orientations or positional relationships based on those shown in the accompanying drawings, and are only intended to facilitate the description of the embodiments of the present invention and to simplify the description, and are not indicative of, or suggestive of, the fact that the device or element referred to must have a particular orientation, be constructed and operated in a particular orientation, and therefore cannot be construed as a limitation of the present invention.

In addition, the terms “first” and “second” are used only for the purpose of description, and are not to be understood as indicating or implying relative importance or implying the number of technical features indicated. As a result, the features defined “first” and “second” may include one or more such features explicitly or implicitly. In the Description of the embodiments of the present invention, “multiple” means two or more, unless otherwise specifically defined.

In the embodiments of the present invention, unless otherwise expressly specified and defined, the terms “installed”, “connected”, “connected”, “fixed” and so on should be broadly understood. For example, it may be a fixed connection, or may be a detachable connection, or may be an integrated connection; it can be mechanical connection or electric connection; It can be directly connected or indirectly connected through the intermediate substrate, and it can be a connection within two elements or an interaction between two elements. The specific meaning of the above terms in the embodiments of the present invention may be understood by those of ordinary skill in the art according to the specific circumstances.

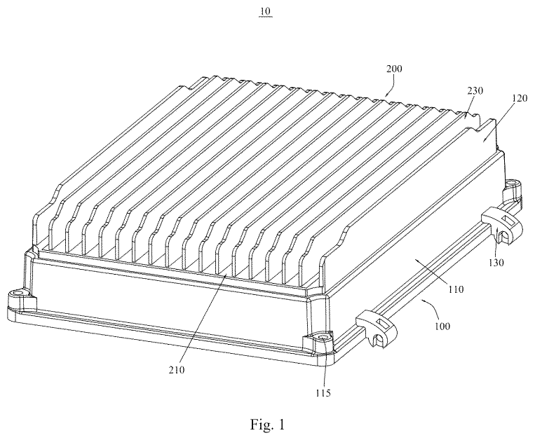

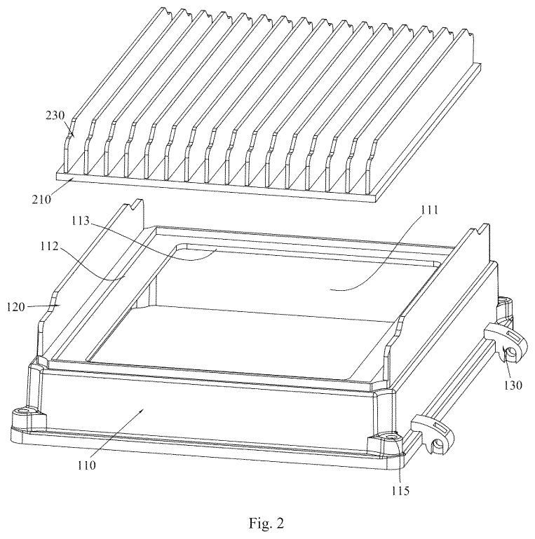

As shown in FIGS. 1-4, a heat sink 10 includes a bottom frame 100 and heat dissipation element 200. A side of the bottom frame 100 is provided with a recessed cavity 111 for receiving a heat element, the other side of the bottom frame 100 away from the recessed cavity 111 is provided with a step groove 112, an inner bottom wall of the step groove 112 is provided with a through slot 113 in communication with the recessed cavity 111. The heat dissipation element 200 includes a heat-conducting plate 210, a heat-conducting protrusion 220, and several heat dissipation teeth 230. Each heat dissipation tooth 230 is spaced apart on the same side of the heat-conducting plate 210, and the heat-conducting protrusion 220 is arranged on the side of the heat-conducting plate 210 away from the heat dissipation teeth 230. The heat-conducting plate 210 is adaptively accommodated in the step groove 112, and the heat-conducting protrusion 220 is passed through the through slot 113. The outer wall of the heat-conducting protrusion 220 is hermetically connected to the inner wall of the through slot 113.

It should be noted that heating elements such as electronic devices are used to be installed in the recessed cavity 111, so that the heating elements are in full contact with the heat sink 10. On the other side of the bottom frame 100 is provided with the step groove 112, and a through slot 113 communicated to the recessed cavity 111 is provided on the inner bottom wall of the step groove 112. Furthermore, the heat-conducting protrusion 220 is located on one side of the heat-conducting plate 210, and each heat dissipation teeth 230 is located on the other side of the heat-conducting plate 210 and spaced apart.

In this way, the heat dissipation element 200 and the bottom frame 100 are independent structures that can be processed and manufactured separately. After the bottom frame 100 and the heat dissipation element 200 are manufactured, the heat dissipation element 200 is installed inside the bottom frame 100. Specifically, the heat-conducting plate 210 is embedded in the step groove 112, so that the heat-conducting protrusion 220 passes through the through slot 113, and the surface of the heat-conducting protrusion 220 is flush with the inner bottom wall of the recessed cavity 111. Then, the outer wall of the heat-conducting protrusion 220 is hermetically connected to the inner wall of the through slot 113 to form a combined structure of the heat sink 10.

In this way, the heat sink 10 is configured as a combined structure in which the bottom frame 100 and the heat dissipation element 200 are installed, with the heat dissipation element 200 serving as the main heat sink. In order to improve the efficiency of the heat dissipation, high heat-conducting materials are selected. The heat dissipation element 200 can be produced through processes such as aluminum extrusion, copper or aluminum machining, scraping, and even high heat-conducting material die-casting. The bottom frame 100 is used for connecting the heat dissipation element 200 and the equipment and ensures the relative position and structural accuracy. Therefore, with respect to the heat dissipation element 200, the requirements for the heat dissipation efficiency of the bottom frame 100 are lower, and the bottom frame 100 can be manufactured using die casting by using a material convenient for die casting. Therefore, even if the structure of the bottom frame 100 is designed specifically for installation, it can greatly reduce the manufacturing difficulty of the heat sink 10, effectively improve the qualification rate of the heat sink 10, facilitate mass production, and effectively ensure that the heat sink 10 has excellent thermal conductivity and heat dissipation performance.

In one embodiment, when the heat dissipation element 200 is a shovel tooth, especially the heat dissipation teeth 230 are high, dense, and thin, in order to avoid deformation or even breakage, a ventilated and breathable protective cover can be installed on the heat dissipation element 200 to protect the heat dissipation teeth 230.

In one embodiment, the outer wall of the heat-conducting protrusion 220 and can be bonded to the through slot 113 with adhesive thermal conductive adhesive, ensuring a sealed installation between the heat-conducting protrusion 220 and the bottom frame 100, while ensuring stable heat transfer from the bottom frame 100 to the heat dissipation component 200.

Furthermore, in one embodiment, the heat dissipation element 200 and the bottom frame 100 can also be locked by fasteners such as bolts, the heat dissipation element 200 and the bottom frame 100 are hermetically connected by a sealing ring.

Furthermore, in one embodiment, the outer wall of the heat-conducting protrusions 220 is welded to the inner wall of the through slot 113, ensuring good sealability and thermal conductivity efficiency between the heat-conducting protrusion 220 and the bottom frame 100. For example, the heat-conducting protrusion 220 and the inner sidewall of the through slot 113 may be welded in one manner of arc welding, laser welding, electron beam welding, resistance welding, gas welding, friction welding, and stir friction welding. Specifically, the welding quality of stir friction welding is stable, without common welding defects such as porosity and cracks, and it has good sealing performance and can effectively improve the mechanical properties between the heat-conducting protrusion 220 and the bottom frame 100. Therefore, stir friction welding is preferred to hermetically connect the heat-conducting protrusion 220 and the bottom frame 100.

As shown in FIGS. 1-4, in one embodiment, the bottom frame 100 includes a frame body 110 and two surrounding plates 120. The recessed cavity 111, the step groove 112, and the through slot 113 all are located in the frame body 110. The two surrounding plates 120 are both provided on a sidewall of the frame body 110 close to the step groove 112 respectively, and are located on two opposite sides of the stepped groove 112.

It should be noted that the two surrounding plates 120 are both located on the side of the frame body 110 close to the step groove 112. In this way, when the heat dissipation element 200 is mounted in the step groove 112, the two surrounding plates 120 are located on the two sides of the heat dissipation teeth 230. And the extension line along the length direction of each surrounding plate 120 is parallel to the extension line along the length direction of the heat dissipation teeth 230. In this way, the two surrounding plates 120 are used for protecting the heat dissipation teeth 230 and avoiding them from deforming due to collision. Further, in one embodiment, the thickness of each surrounding plate 120 is gradually decreases in a direction away from the frame body 110. Thus, when the bottom frame 100 is manufactured by means of die-casting, it is convenient to demould the surrounding plate 120. In one embodiment, the less thickness of the surrounding plate 120 is bigger than the thickness of the heat dissipation teeth 230. In this way, the surrounding plate 120 0 can effectively protect the heat dissipation teeth 230.

As shown in FIG. 1, in one embodiment, the outer sidewall of the frame body 110 is provided with two external connection lugs 130 at intervals.

It should be noted that the recessed cavity 111 is used to receiving the heat element with large volume, therefore to convenient to the assemble and dis assemble of the heat sink 10 and the heating element, the outer sidewall of the frame body 110 is provided with two external connection lugs 130 at intervals. Thus, the frame body 110 and the heating element can be hingedly mounted via the two external connection lugs 130, so that the frame body 110 is fastened to the heating element or is lifted off the heating element.

Further, in one embodiment, the frame body 110, the two surrounding plates 120, the two external connection lugs 130 are integrally formed into the bottom frame 100 by means of die casting. Thus, the bottom frame 100 manufactured by means of die casting has sufficient structural strength between the frame body 110, the two surrounding plates 120 and the two external connection lugs 130.

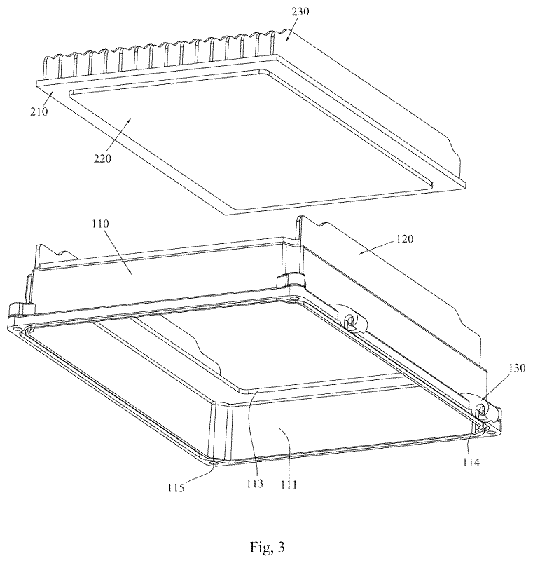

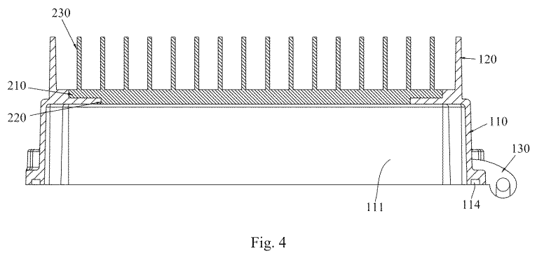

As shown in FIGS. 3-4, in one embodiment, a closed sealing groove 114 is formed on the frame 110 surrounding the periphery of the recessed cavity 111.

Thus, when the heat sink 10 is mounted on the heat element for use, a sealing ring is mounted in the sealing groove 114 to ensure that good sealing performance is maintained in the recessed cavity 111.

As shown in FIG. 1, in one embodiment, the frame body 110 is provided with a plurality of locking holes 115 spaced apart from each other, which are used for inserting screws, so that the bottom frame 100 is easy to install.

In one embodiment, the surface of the heat sink 10 is provided with a protective layer, for example, the surface of the radiator 10 may form the protective layer by one of anodizing treatment, sandblasting treatment, spray coating treatment, nickel plating or chrome plating treatment, chemical conversion molding treatment, and wire drawing treatment. In the disclosure, the protective layer is preferably formed on the surface of the radiator 10 by means of spray coating treatment, and thus the whole heat dissipation efficiency, corrosion resistance and abrasion resistance of the radiator 10 can be further improved.

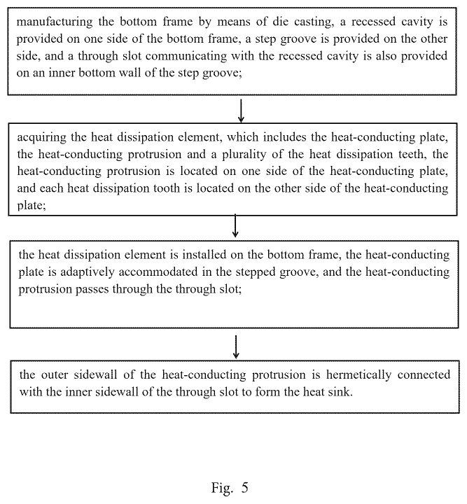

As shown in FIG. 5, a methods for producing the heat sink includes the following steps:

Step S10: manufacturing the bottom frame by means of die casting, the recessed cavity is provided on one side surface of the bottom frame, the step groove is provided on the other side surface, and the through slot communicating with the recessed cavity is also provided on an inner bottom wall of the step groove;

Step S20: acquiring the heat dissipation element, which includes the heat-conducting plate, the heat-conducting protrusion and a plurality of the heat dissipation teeth, the heat-conducting protrusion is located on one side surface of the heat-conducting plate, and each of the heat dissipation teeth is located on the other side surface of the heat-conducting plate;

Step 30: the heat dissipation element is installed on the bottom frame, the heat-conducting plate is adaptively accommodated in the stepped groove, and the heat-conducting protrusion passes through the through slot.

Step S40: the outer sidewall of the heat-conducting protrusion is hermetically connected with the inner sidewall of the through slot to form the heat sink.

It should be noted that the bottom frame is integrally formed by means of die casting, which not only improve the manufacturing efficiency of the bottom frame, but also ensure the structural size and the overall structural strength of the bottom frame effectively. For example, the bottom frame may be formed by die-casting an ADC12 aluminum material, thereby having good casting performance, high mechanical strength, and being capable of bearing a certain load. Further, in another embodiment, the bottom frame is formed by die-casting a magnesium alloy, and the magnesium alloy is an alloy material formed by adding at least one element of aluminum, zinc, manganese and zirconium on the basis of magnesium. In this way, the overall weight of the bottom frame can be reduced, and the purpose of weight reduction is achieved. Thus, the heat sink in an independent state and the bottom frame are installed in a sealed manner as an integrated radiator, and the bottom frame can be designed to have any specific structure according to different heat elements, thereby effectively ensuring the heat dissipation efficiency of the radiator and reducing the manufacturing difficulty of the radiator at the same time.

Further, in an embodiment, in the step S20, the heat dissipation element is obtained by one of processes such as extruding aluminum, machining copper or aluminum, shoveling teeth, and even die-casting a high thermal conductivity material.

It should be noted that in one embodiment, the heat dissipation element is manufactured by processes such as extruding aluminum, machining copper or aluminum, shoveling teeth, and even die-casting a high thermal conductivity material, for example, the heat dissipation element can be made of A6063 aluminum and copper, which has good extrusion performance, good corrosion resistance, good soldering performance, and can also improve the strength by heat treatment.

Further, in an embodiment, in the step S40, the outer sidewall of the heat conducting protrusions and the inner sidewall of the through slot are hermetically connecting by friction stir welding.

It should be noted that, the heat-conducting protrusion and the bottom frame are welded and fixed by using the stir friction welding process, so that on the one hand, sufficient tightness is maintained between the heat sink and the bottom frame, and on the other hand, heat of the bottom frame may also be quickly transferred to the heat dissipation element for heat dissipation.

The foregoing embodiments merely represent several implementations of the disclosure, and are described in detail, but are not intended to limit the scope of the disclosure. Unless otherwise defined, the mounting/fixing/setting mentioned in the disclosure can be understood as including but not limited to fixing and welding using screws/screws. It should be noted that, for those skilled in the art, various modifications and improvements can be made without departing from the concept of the disclosure, and all these modifications and improvements belong to the scope of protection of the disclosure. Therefore, the scope of protection of the disclosure should be subject to the appended claims.

What is claimed is:

1. A heat sink, comprising
a bottom frame, a side of said bottom frame is provided with a recessed cavity for receiving a heat element, the other side of said bottom frame away from said recessed cavity is provided with a step groove, an inner bottom wall of said step groove is provided with a through slot in communication with said recessed cavity; and
a heat dissipation element, comprising a heat-conducting plate, a heat-conducting protrusion, and several heat dissipation teeth; each heat dissipation tooth is spaced apart on same side of said heat-conducting plate, and said heat-conducting protrusion is arranged on said side of the heat-conducting plate away from said heat dissipation teeth; said heat-conducting plate is adaptively accommodated in said step groove, and said heat-conducting protrusion is passed through said through slot; an outer wall of said heat-conducting protrusion is hermetically connected to an inner wall of said through slot.

2. The heat sink according to claim 1, wherein said outer wall of the heat-conducting protrusions is welded to said inner wall of the through slot.

3. The heat sink according to claim 2, wherein said outer wall of said heat-conducting protrusion and said inner wall of the through slot is welded by stir friction welding.

4. The heat sink according to claim 3, wherein said bottom frame includes a frame body and two surrounding plates; said recessed cavity, said step groove, and said through slot all are located in said frame body; said two surrounding plates are both provided on a sidewall of said frame body close to said step groove, and are located on two opposite sides of said stepped groove.

5. The heat sink according to claim 4, wherein said outer wall of the frame body is provided with two external connection lugs at intervals.

6. The heat sink according to claim 5, wherein said frame body, said two surrounding plates, said two external connection lugs are integrally formed into said bottom frame by means of die casting.

7. The heat sink according to claim 6, wherein a closed sealing groove is formed on said frame surrounding a periphery of said recessed cavity.

8. The heat sink according to claim 6, wherein said frame body is provided with a plurality of locking holes spaced apart from each other.

9. The heat sink according to claim 6, wherein a surface of said heat sink is provided with a protective layer.
